(19) United States
(12) Patent Application Publication
(10) Pub. No.: US 2012/0074559 A1
(43) Pub. Date: Mar. 29, 2012

(54) INTEGRATED CIRCUIT PACKAGE USING THROUGH SUBSTRATE VIAS TO GROUND LID

(75) Inventors: Timothy W. Budell, Westford, VT (US); Mark C.H. Lamorey, South Burlington, VT (US); Peter Slota, JR., Vestal, NY (US)

(73) Assignee: INTERNATIONAL BUSINESS MACHINES CORPORATION, Armonk, NY (US)

(21) Appl. No.: 12/889,586

(22) Filed: Sep. 24, 2010

(51) Int. Cl. H01L 23/29

(52) U.S. Cl. 257/699; 257/E23.011

(57) ABSTRACT

An integrated circuit package including a package substrate, a metal lid mounted to the package substrate, and a stack of two or more integrated circuit chips electrically connected to each other by through substrate vias. The stack of two or more integrated circuit chips is disposed within the metal lid and electrically mounted to the package substrate. An inner surface of a top of the metal lid is electrically connected to ground wires in the package substrate by the through substrate vias. The TSVs provide electromagnetic interference shielding. A conductive thermal interface material may also be used. An alternative embodiment includes a single integrated circuit chip using TSVs to ground the metal lid.

### BACKGROUND

1. Technical Field

The disclosure relates generally to integrated circuit (IC) chips, and more particularly, to an integrated circuit package using through substrate vias to ground a lid to, for example, limit electro-magnetic interference.

2. Background Art

Regulations exist to limit the extent of electro-magnetic interference (EMI) for a given integrated circuit (IC) chip. EMI can be limited in a number of ways. One currently evolving manner of limiting EMI is to provide a grounded lid to an IC chip. When a ground lid is used, a lip of the metal lid is electrically coupled to a ground plane in the package substrate (i.e., laminate) using a ball grid array (BGA) of the package substrate and/or controlled collapse chip connectors (C4) between the package substrate and the IC chip. The metal lid acts to suppress EMI through its grounded connection. However, the effectiveness of the lid is limited because only a small portion of the lid is effectively grounded for the frequency of EMI emissions, i.e., the outer lip. Consequently, the grounding efficacy is not uniform across the lid for all emission frequencies.

### BRIEF SUMMARY

A first aspect of the disclosure provides an integrated circuit package, comprising: a package substrate; a metal lid mounted to the package substrate; and a stack of two or more integrated circuit chips electrically connected to each other by through substrate vias, the stack of two or more integrated circuit chips disposed within the metal lid and electrically mounted to the package substrate, wherein an inner surface of a top of the metal lid is electrically connected to ground wires in the package substrate by the through substrate vias.

A second aspect of the disclosure provides an integrated circuit package, comprising: a package substrate; a metal lid mounted to the package substrate; a stack of two or more integrated circuit chips electrically connected to each other by axially aligned through substrate vias running from a bottom of a lowermost integrated circuit chip of the two or more integrated circuit chips to an upper surface of an uppermost integrated circuit chip of the two or more integrated circuit chips, the stack of two or more integrated circuit chips disposed within the metal lid and electrically mounted to the package substrate; and a conductive thermal interface material (TIM) between the upper surface of the uppermost integrated circuit chip and the metal lid, wherein an inner surface of a top of the metal lid is electrically connected to ground wires in the package substrate by the conductive TIM and the through substrate vias.

A third aspect of the disclosure provides an integrated circuit package, comprising: a package substrate; a metal lid mounted to the package substrate; and an integrated circuit chip including a plurality of through substrate vias running from a bottom of the integrated circuit chip to an upper surface of the integrated circuit chip, wherein an inner surface of a top of the metal lid is electrically connected to ground wires in the package substrate by the through substrate vias.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a cross-sectional view of embodiments of an integrated circuit package according to embodiments of the invention.

FIG. 2 shows a cross-sectional view of alternative embodiments of an integrated circuit package according to embodiments of the invention.

FIG. 3-5 show cross-sectional views of embodiments of an integrated circuit package according to alternative embodiments of the invention.

FIG. 6 shows a cross-sectional view of an alternative embodiment of an integrated circuit package according to embodiments of the invention.

FIG. 7 shows a cross-sectional view of an alternative embodiment of an integrated circuit package according to embodiments of the invention.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

As indicated above, the disclosure provides an integrated circuit package including a package substrate, a metal lid mounted to the package substrate, and a stack of two or more integrated circuit chips electrically connected to each other by through substrate vias. The stack of two or more integrated circuit chips is disposed within the metal lid and electrically mounted to the package substrate. An inner surface of a top of the metal lid is electrically connected to ground wires in the package substrate by the through substrate vias (TSVs). The TSVs provide electromagnetic and radio frequency interference shielding. A conductive thermal interface material may also be used.

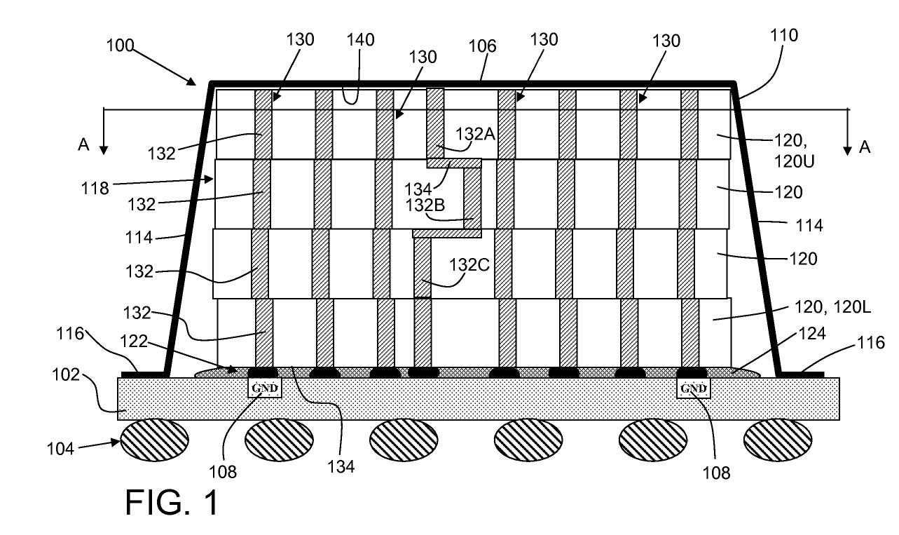

Referring to FIG. 1, embodiments of an integrated circuit (IC) package 100 will now be described. IC package 100 includes a package substrate 102. Package substrate 102 may include a multilayer ceramic or a plastic laminate. A conventional grid array 104, e.g., ball grid array (BGA), column grid array (CGA), land grid array (LGA) or pin grid array (PGA), connects package substrate 102 to a card such as printed circuit board (PCB) (not shown). Package substrate 102 includes ground wiring 108 therein. Other wiring (not shown) may include any variety of well known wiring or circuitry, e.g., power or data transfer wiring.

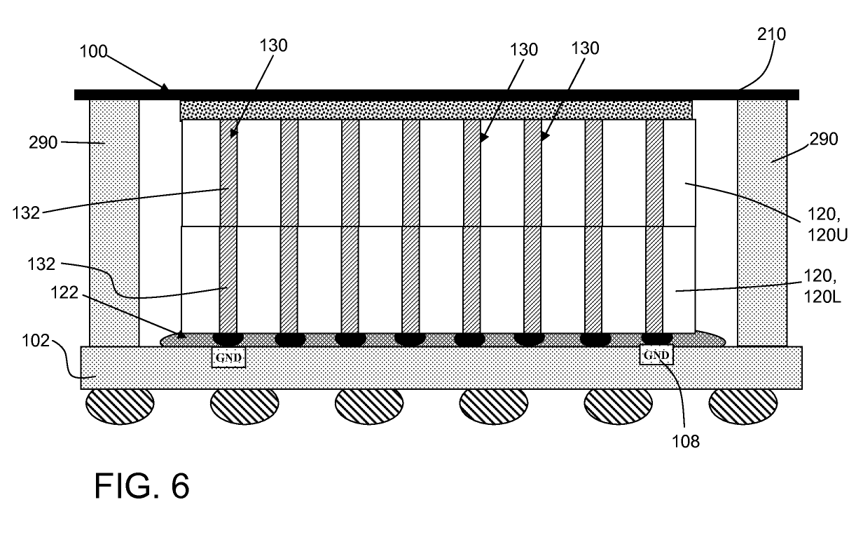

A metal lid 110 is mounted to package substrate 102. Metal lid 110 may be made of any now known or conventional material typically used for a lid of a chip package, e.g., aluminum, copper, etc., or alloys thereof. Metal lid 110 is mechanically positioned on chips 120 and has a thickness greater than a simple coating, the latter of which could be applied by a chemical process. Metal lid 110 could be removed and/or replaced using mechanical tools, and could not be positioned within a chip 120. Although not shown for clarity, it is understood that metal lid 110 could also include other conventional thermal transfer structures such as a heat sink or a heat spreader (not shown). As illustrated metal lid 110 includes a top 106 and sidewalls 114. As illustrated, metal lid 110 completely surrounds a top and sidewalls of a stack 118 of two or more integrated circuit (IC) chips 120. That is, sidewalls 114 may exist on four sides of metal lid 110 so as to create an open, rectangular box shape (open downwardly as drawn). However, as shown in FIG. 6, enclosure of a metal lid 210 on all sides is not necessary in all cases. As shown in FIG. 6, metal lid 210 may be open on sides thereof and coupled to package substrate 102 by structures 290. Metal lid 110 may also include flanges 116 for mechanically connecting sidewalls 114 to package substrate 102 using any now known or later developed solution, e.g., adhesive such as polymer or solder, or mechanical connectors such as rivets, screws, etc. Also, other structures such as an elastomeric gasket, O-ring, metal seal or similar contact configuration have been omitted for clarity.

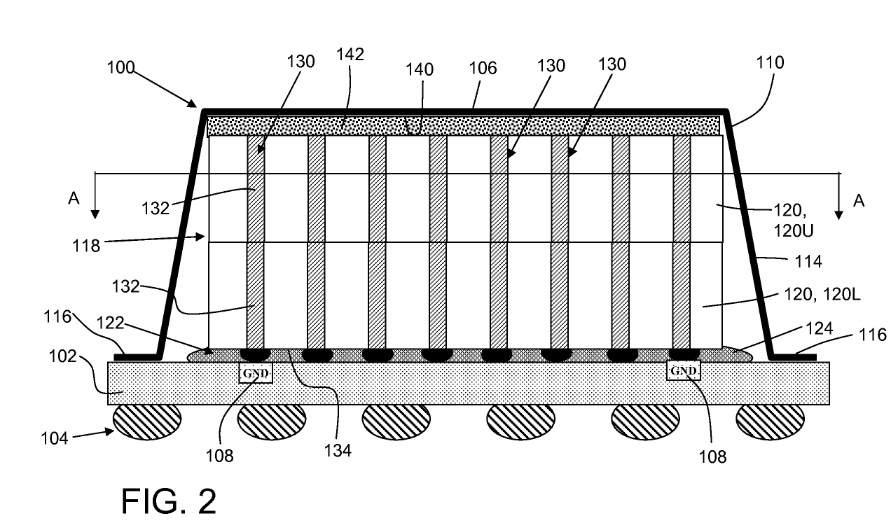

A stack 118 of two or more integrated circuit (IC) chips 120 are disposed within metal lid 110 and electrically mounted to package substrate 102. In FIG. 1, four IC chips 120 are shown; it is understood, however, that any number of two or more may be employed. For example, the FIG. 2 embodiment shows just two IC chips 120. A lowermost IC chip 120L is electrically connected to package substrate 102 by solder connections 122, e.g., controlled collapse chip connectors (C4), and under-fill material 124. In addition, the stack 118 of two or more IC chips 120 are electrically connected to each other by through substrate vias (TSVs) 130. In one embodiment, respective TSVs 132 of each IC chip 120 of the two or more integrated circuit chips are aligned along respective axes running from a bottom 134 of lowermost IC chip 120L to an upper surface of an uppermost IC chip 120U of the two or more integrated circuit chips. That is, each IC chip 120 includes at least one TSV 132 that is axially aligned with a TSV 132 in at least one adjacent IC chip. As shown in FIG. 1, it is also possible, however, that all TSVs 132A, B, C are not exactly axially aligned. In this case, other wiring 134 may be used to couple TSVs 132A, B, C. In one embodiment, as illustrated, a plurality of axially aligned TSVs 130 (sets of TSVs) extend through each IC chip 120 of the two or more IC chips 120. TSVs 130 may include any now known or later developed material, e.g., tungsten, copper, heavily doped polysilicon, aluminum, etc., and any refractory metal liner material, e.g., titanium nitride, etc.

In accordance with embodiments of the invention, an inner surface 140 of top 106 of metal lid 110 is electrically connected to ground wires 108 in package substrate 102 by through substrate vias 130. That is, TSVs 130 extend through an upper surface of uppermost chip 120U and are exposed such that they can contact inner surface 140 of top 106 of metal lid 110 (or TIM 142 where used, described elsewhere herein). Use of TSVs 130 to make the connection to metal lid 110 lowers the resistance path between metal lid 110 and chips 120 and package substrate 102. In addition, TSVs 130 provide a set of off-axis antennas to absorb and synchronize additional electromagnetic radiation. A metal lid to chip to package substrate connection allows provision of structures closer to a Faraday cage to isolate IC chips 120 from electromagnetic interference (EMI) and maintain chips 120 from affecting their surroundings with EMI.

Referring to FIG. 2, in another embodiment, a conductive thermal interface material (TIM) 142 may be disposed between inner surface 140 of top 106 of metal lid 110 and TSVs 130. In this fashion, metal lid 110 may be conductively and thermally coupled by conductive TIM 142 to uppermost IC chip 120U to provide a conductive and thermal path from uppermost chip 120U and all of the TSVs 130 to metal lid 110. In this fashion, the current density can be more uniformly dispersed, enhancing electromagnetic suppression since both metal lid 110 and TIM 142 act to sink or suppress electromagnetic emissions. Moreover, TSVs 130 can be used for thermal solution improvements by providing a stronger thermal coupling between silicon of IC chips 120, TIM 142 and package substrate 102. TIM 142 may include any now known or later developed conductive thermal interface material such as a thermal paste, liquid, phase change material and other materials.

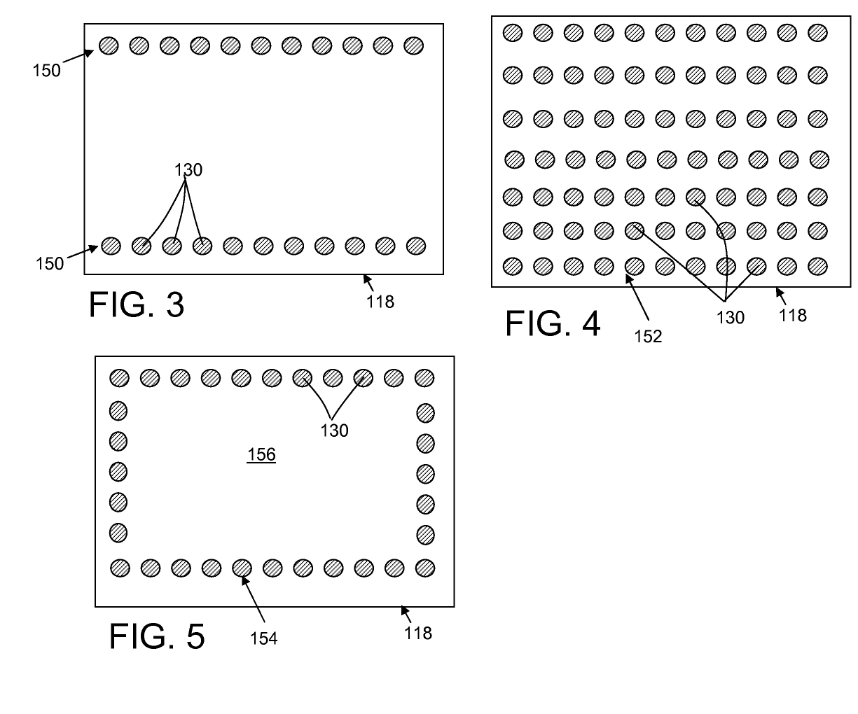

Referring to FIGS. 3-5, cross-sectional views along lines A-A in FIGS. 1-2 illustrating how TSVs 130 may be arranged in a number of ways. TSVs 130 may be arranged in different configurations to enhance, among other things, electromagnetic shielding and thermal transmission. FIG. 3 illustrates plurality of axially aligned TSVs 130 extending in at least one plane 150 (two shown) in the stack 118 of two or more IC chips 120. In an alternative embodiment, shown in FIG. 4, the plurality of axially aligned TSVs 130 may be arranged in an array 152 in the stack 118 of two or more IC chips. As illustrated, array 152 exhibits substantially uniform spacing; however, this is not necessary in all cases. An array 152 is advantageous, among other reasons, because it more evenly distributes current density, enhancing the electromagnetic suppression. In another alternative embodiment, shown in FIG. 5, the plurality of axially aligned TSVs 130 are arranged in a pattern 154 in the stack 118 of two or more IC chips having an open area 156 therein. Although shown as a rectangular pattern 154, any open shape is possible. The open pattern employed here allows metal lid 110 to more closely resemble a Faraday cage, thus enhancing electromagnetic suppression.

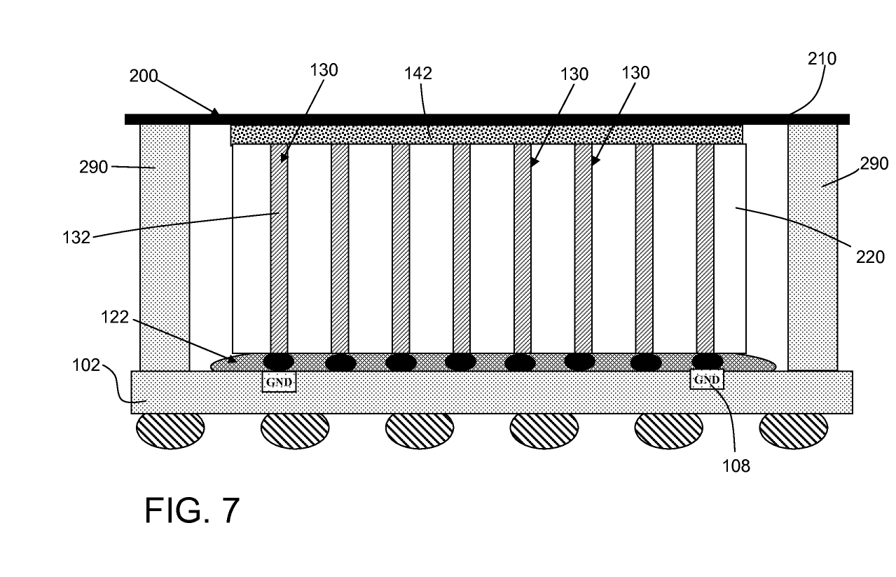

Although IC chip package 100 has been described herein as including a stack 118 of IC chips 120, in an alternative embodiment, shown in FIG. 7, an IC chip package 200 may include a single IC chip 220 including TSVs 130 as described herein. Although shown with metal lid 210 of FIG. 6, it is understood that the metal lid of FIG. 7 could be the same as that of FIGS. 1-2. Further, IC chip package 200 may or may not employ TIM 142.

The above-described integrated circuit packages can be distributed by the fabricator as is or may be combined into another multichip package (such as a ceramic carrier that has either or both surface interconnections or buried interconnections). In any case the chips are then integrated with other chips, discrete circuit elements, and/or other signal processing devices as part of either (a) an intermediate product, such as a motherboard, or (b) an end product. The end product can be any product that includes integrated circuit chips, ranging from cell phones, toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. An integrated circuit package, comprising:
a package substrate;
a metal lid mounted to the package substrate; and
a stack of two or more integrated circuit chips electrically connected to each other by through substrate vias, the stack of two or more integrated circuit chips disposed within the metal lid and electrically mounted to the package substrate,
wherein an inner surface of a top of the metal lid is electrically connected to ground wires in the package substrate by the through substrate vias.

2. The integrated circuit package of claim 1, wherein the metal lid includes sidewalls connected to the top of the metal lid and the sidewalls are mechanically connected to an upper surface of the package substrate.

3. The integrated circuit package of claim 1, wherein the metal lid completely surrounds a top and sidewalls of the stack of two or more integrated circuit chips.

4. The integrated circuit package of claim 1, wherein respective through substrate vias of each integrated circuit chip of the two or more integrated circuit chips are aligned along respective axes running from a bottom of a lowermost integrated circuit chip of the two or more integrated circuit chips to an upper surface of an uppermost integrated circuit chip of the two or more integrated circuit chips.

5. The integrated circuit package of claim 4, further comprising a plurality of axially aligned through substrate vias extending through of each integrated circuit chip of the two or more integrated circuit chips.

6. The integrated circuit package of claim 5, wherein the plurality of axially aligned through substrate vias extend in at least one plane in the stack of two or more integrated circuit chips.

7. The integrated circuit package of claim 5, wherein the plurality of axially aligned through substrate vias are arranged in an array in the stack of two or more integrated circuit chips.

8. The integrated circuit package of claim 5, wherein the plurality of axially aligned through substrate vias are arranged in a pattern in the stack of two or more integrated circuit chips having an open area therein.

9. The integrated circuit package of claim 1, further comprising a conductive thermal interface material (TIM) between the inner surface of the top of the metal lid and the through substrate vias.

10. An integrated circuit package, comprising:
a package substrate;
a metal lid mounted to the package substrate;
a stack of two or more integrated circuit chips electrically connected to each other by axially aligned through substrate vias running from a bottom of a lowermost integrated circuit chip of the two or more integrated circuit chips to an upper surface of an uppermost integrated circuit chip of the two or more integrated circuit chips, the stack of two or more integrated circuit chips disposed within the metal lid and electrically mounted to the package substrate; and
a conductive thermal interface material (TIM) between the upper surface of the uppermost integrated circuit chip and the metal lid,
wherein an inner surface of a top of the metal lid is electrically connected to ground wires in the package substrate by the conductive TIM and the through substrate vias.

11. The integrated circuit package of claim 10, wherein the metal lid includes sidewalls connected to the top of the metal lid and the sidewalls are mechanically connected to a top surface of the package substrate.

12. The integrated circuit package of claim 10, wherein the metal lid completely surrounds a top and sidewalls of the stack of two or more integrated circuit chips.

13. The integrated circuit package of claim 10, further comprising a plurality of axially aligned through substrate vias extending through of each integrated circuit chip of the two or more integrated circuit chips.

14. The integrated circuit package of claim 13, wherein the plurality of axially aligned through substrate vias extend in at least one plane in the stack of two or more integrated circuit chips.

15. The integrated circuit package of claim 13, wherein the plurality of axially aligned through substrate vias are arranged in an array in the stack of two or more integrated circuit chips.

16. The integrated circuit package of claim 13, wherein the plurality of axially aligned through substrate vias are arranged in a pattern in the stack of two or more integrated circuit chips having an open area therein.

17. An integrated circuit package, comprising:
a package substrate;
a metal lid mounted to the package substrate; and
an integrated circuit chip including a plurality of through substrate vias running from a bottom of the integrated circuit chip to an upper surface of the integrated circuit chip,
wherein an inner surface of a top of the metal lid is electrically connected to ground wires in the package substrate by the through substrate vias.

18. The integrated circuit package of claim 17, wherein the metal lid includes sidewalls connected to the top of the metal lid and the sidewalls are mechanically connected to a top surface of the package substrate.

19. The integrated circuit package of claim 17, wherein the plurality of through substrate vias extend in at least one plane in the integrated circuit chip.

20. The integrated circuit package of claim 17, wherein the plurality of through substrate vias are arranged in an array in the integrated circuit chip.
